(19) United States
(12) Patent Application Publication
(10) Pub. No.: US 2026/0123139 A1
(43) Pub. Date: Apr. 30, 2026

(54) DISPLAY APPARATUS AND MANUFACTURING METHOD THEREOF

(71) Applicant: AUO Corporation, Hsinchu City (TW)

(72) Inventors: Jui-Ping Yu, Hsinchu City (TW); Kuan-Lin Kuo, Hsinchu City (TW); Shih-Pin Cheng, Hsinchu City (TW)

(73) Assignee: AUO Corporation, Hsinchu City (TW)

(21) Appl. No.: 19/242,923

(22) Filed: Jun. 18, 2025

(30) Foreign Application Priority Data
Oct. 30, 2024 (TW) 113141441

(51) Int. Cl. H10H 29/49; G09G 3/00; H01L 25/16; H10H 29/01; H10H 29/855

(52) U.S. Cl. CPC H10H 29/49; G09G 3/006; H10H 29/012; H10H 29/0363; H10H 29/0364; H10H 29/8552; H10W 90/00; G09G 2330/12

(57) ABSTRACT

A display apparatus includes a driving circuit substrate having pixel driving structures, light emitting element groups, a planarization layer, and a first light shielding layer. Each pixel driving structure includes sub-pixel driving structures. Each sub-pixel driving structure includes a sub-pixel driving circuit, at least one main pad, and at least one repair pad. The planarization layer is disposed on the driving circuit substrate. The first light shielding layer is disposed on the planarization layer. The pixel driving structures include a normal pixel driving structure. The light emitting element groups include a normal light emitting element group. The first light shielding layer includes a first solid portion shielding the at least one repair pad of the normal pixel driving structure and a first opening located above a first light emitting element of the normal light emitting element group. A manufacturing method of the display apparatus is also provided.

### CROSS-REFERENCE TO RELATED APPLICATION

This application claims the priority benefit of Taiwan application serial no. 113141441, filed on Oct. 30, 2024. The entirety of the above-mentioned patent application is hereby incorporated by reference herein and made a part of this specification.

### BACKGROUND

### Technical Field

The disclosure relates to a photoelectric apparatus and a manufacturing method thereof, and more particularly to a display apparatus and a manufacturing method thereof.

### Description of Related Art

With the advancement of display technology, the development of the panel industry is no longer just about pursuing large size and high production capacity utilization, but is moving toward the goal of presenting a higher-level panel image quality. At present, the development trend of panels is gradually shifting from backlight light emission to active light emission. The main reason is that the active light emitting panel has advantages such as being thin and flexible and having a wide color gamut, a wide viewing angle, high contrast, and high resolution, and may present excellent panel image quality and is suitable for more diversified product applications. Among various active light emitting displays, the micro light emitting diode display also has advantages such as local dimming, high brightness, and longer service life, which the organic light emitting diode display does not have. Therefore, the micro light emitting diode display has also become the main development technology of the future panel industry.

In addition to the reflective metal circuit of the driving circuit layer of the micro light emitting diode display, due to the difficulty of mass transfer technology, the repair pad is currently disposed on the substrate in advance. However, generally, the material of the repair pad is metal, and metal has high reflectivity, making it difficult to reduce the overall reflectivity of the micro light emitting diode display panel.

### SUMMARY

The disclosure provides a display apparatus with low reflectivity.

The disclosure provides a manufacturing method of a display apparatus, which may manufacture the display apparatus with low reflectivity.

A display apparatus of the disclosure includes a driving circuit substrate, multiple light emitting element groups, a planarization layer, and a first light shielding layer. The driving circuit substrate has multiple pixel driving structures. Each of the pixel driving structures includes multiple sub-pixel driving structures. Each of the sub-pixel driving structures includes a sub-pixel driving circuit, at least one main pad, and at least one repair pad, and the at least one main pad and the at least one repair pad are electrically connected to the sub-pixel driving circuit. The light emitting element groups are respectively electrically connected to the pixel driving structures. Each of the light emitting element groups includes a first light emitting element. The planarization layer is disposed on the driving circuit substrate and covers the light emitting element groups. The first light shielding layer is disposed on the planarization layer. The pixel driving structures include a normal pixel driving structure. The light emitting element groups include a normal light emitting element group. The normal light emitting element group is electrically connected to the normal pixel driving structure. The first light emitting element of the normal light emitting element group is bonded to the at least one main pad of the normal pixel driving structure. The first light shielding layer includes a first solid portion and a first opening. The first solid portion shields the at least one repair pad of the normal pixel driving structure. The first opening is located above the first light emitting element of the normal light emitting element group.

A manufacturing method of a display apparatus of the disclosure includes the following steps. A driving circuit substrate having multiple pixel driving structures is provided. Each of the pixel driving structures includes multiple sub-pixel driving structures, each of the sub-pixel driving structures includes a sub-pixel driving circuit, at least one main pad, and at least one repair pad, and the at least one main pad and the at least one repair pad are electrically connected to the sub-pixel driving circuit. Multiple light emitting elements are bonded to multiple main pads of the sub-pixel driving structures of the pixel driving structures. A planarization layer is formed on the driving circuit substrate to cover the light emitting elements. A first light shielding layer is formed on the planarization layer. The first light shielding layer has multiple openings, the openings are located above at least part of the light emitting elements, and multiple solid portions of the first light shielding layer shield at least part of multiple repair pads of the pixel driving structures.

### BRIEF DESCRIPTION OF THE DRAWINGS

FIG. 1A to FIG. 1F are top schematic views of a manufacturing process of a display apparatus according to an embodiment of the disclosure.

FIG. 2A to FIG. 2F are cross-sectional schematic views of a manufacturing process of a display apparatus according to an embodiment of the disclosure.

FIG. 3A to FIG. 3F are cross-sectional schematic views of a manufacturing process of a display apparatus according to an embodiment of the disclosure.

FIG. 4A to FIG. 4F are cross-sectional schematic views of a manufacturing process of a display apparatus according to an embodiment of the disclosure.

FIG. 5A to FIG. 5F are cross-sectional schematic views of a manufacturing process of a display apparatus according to an embodiment of the disclosure.

FIG. 6 is a schematic view of an equivalent circuit of a pixel driving structure of a display apparatus according to an embodiment of the disclosure.

### DESCRIPTION OF THE EMBODIMENTS

Reference will now be made in detail to the exemplary embodiments of the disclosure, and examples of the exemplary embodiments are illustrated in the drawings. Wherever possible, the same reference numerals are used in the drawings and the description to represent the same or similar parts.

It should be understood that when an element such as a layer, a film, a region, or a substrate is referred to as being “on” another element or “connected to” another element, the element may be directly on the another element or connected to the another element, or there may be an intermediate element. In contrast, when an element is referred to as being “directly on” another element or “directly connected to” another element, there is no intermediate element. As used herein, “connection” may refer to physical and/or electrical connection. Furthermore, “electrical connection” or “coupling” may be that there is another element between two elements.

As used herein, “about”, “approximately”, or “substantially” includes the stated value and an average value within an acceptable deviation range of the particular value as determined by persons skilled in the art, while taking into account the measurement in discussion and a particular amount of error (that is, the limitation of a measurement system) associated with the measurement. For example, “about” may represent being within one or more standard deviations or within ±30%, ±20%, ±15%, ±10%, or ±5% of the stated value. Furthermore, “about”, “approximately”, or “substantially” used herein may choose a more acceptable deviation range or standard deviation according to optical properties, etching properties, or other properties and may not apply one standard deviation to all properties.

Unless otherwise defined, all terms (including technical and scientific terms) used herein have the same meaning as commonly understood by persons skilled in the art to which the disclosure belongs. It should be understood that the terms, such as those defined in commonly used dictionaries, should be interpreted as having meanings consistent with the prior art and the context of the disclosure, and should be interpreted in an idealized or overly formal manner, unless specifically defined herein.

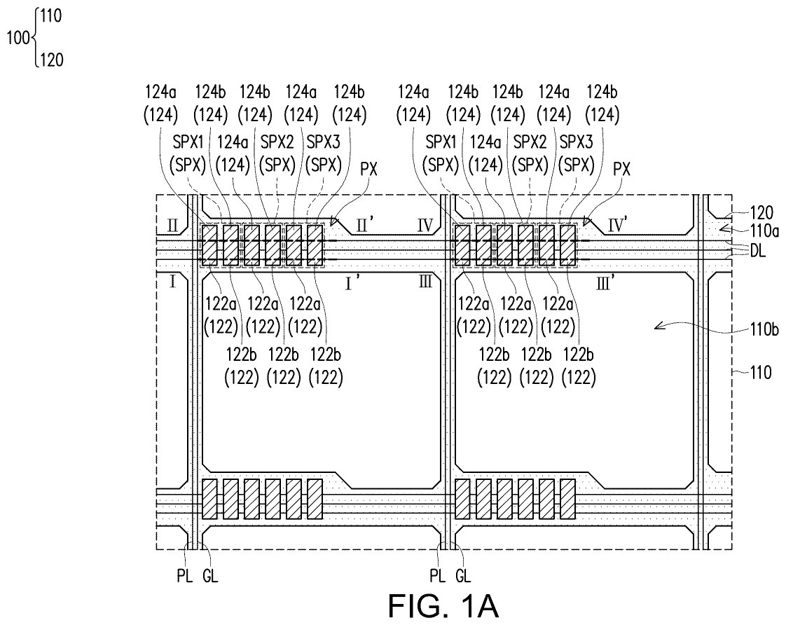

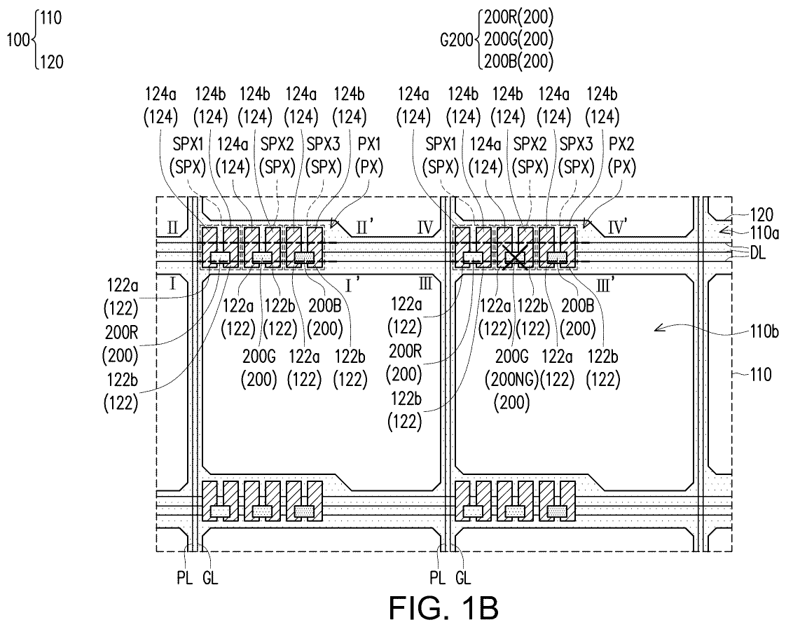

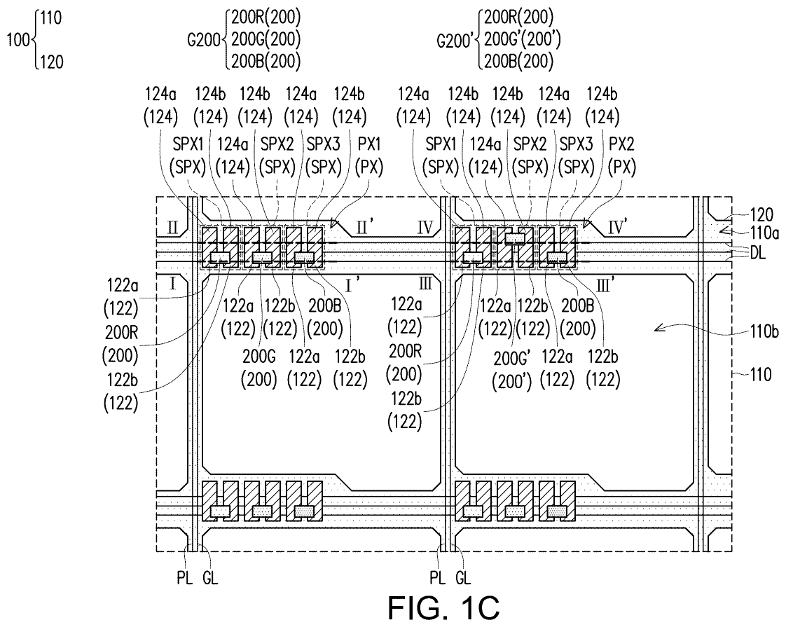

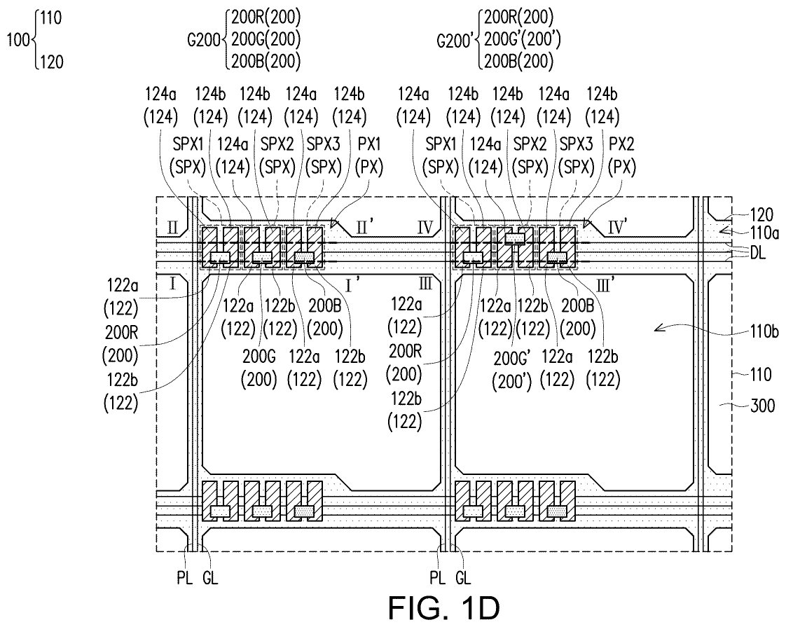

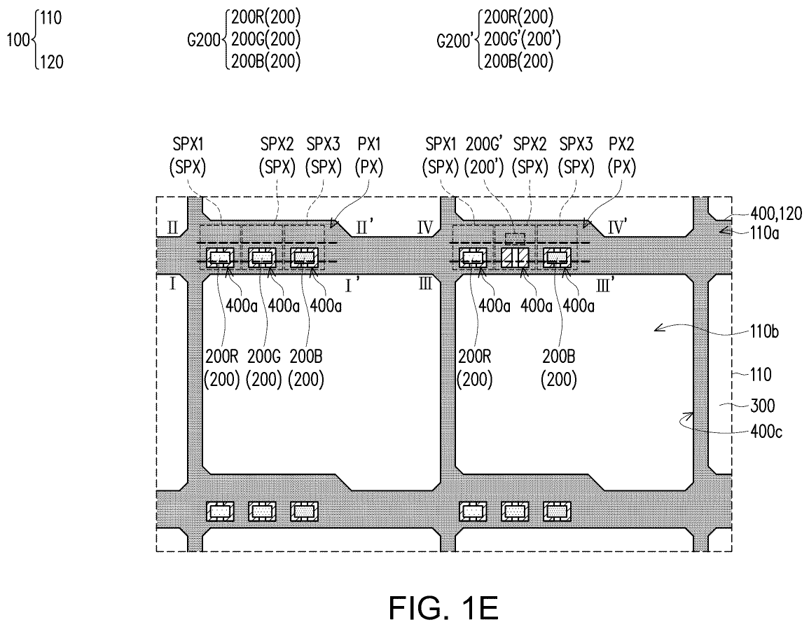

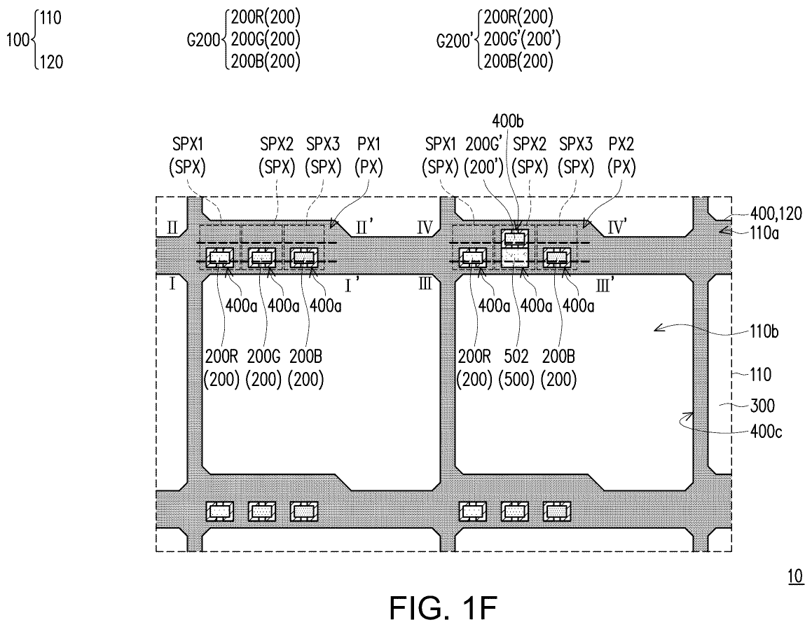

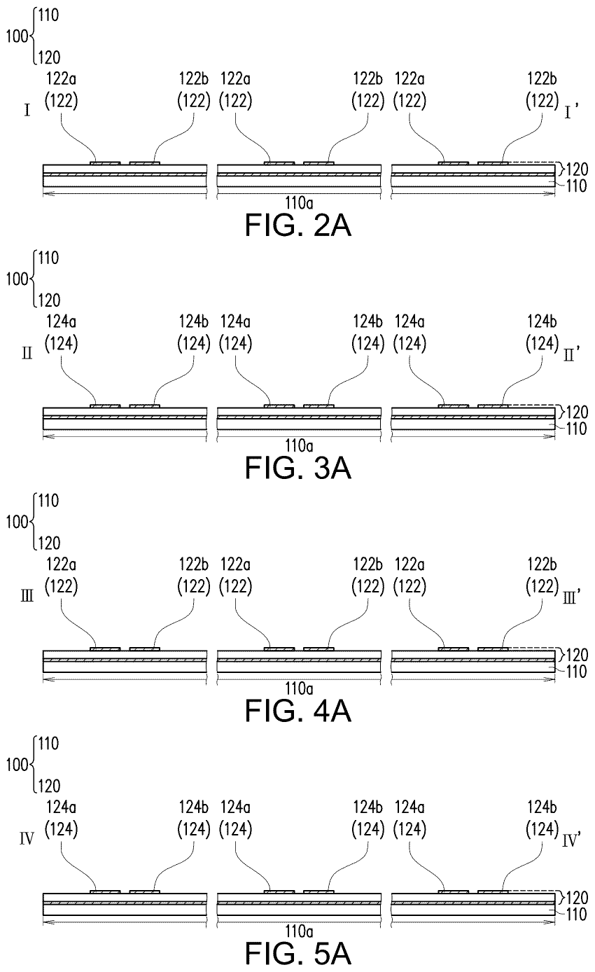

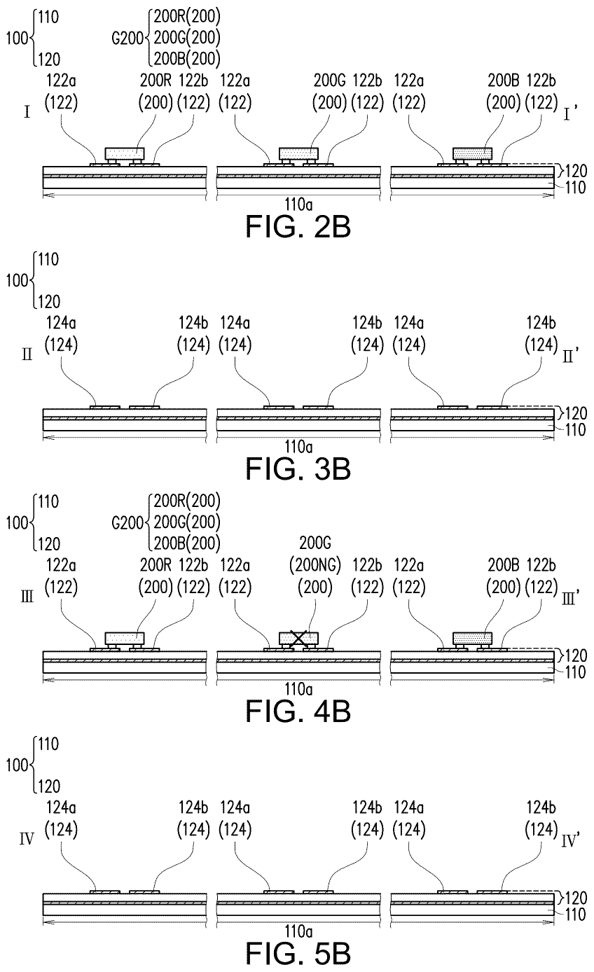

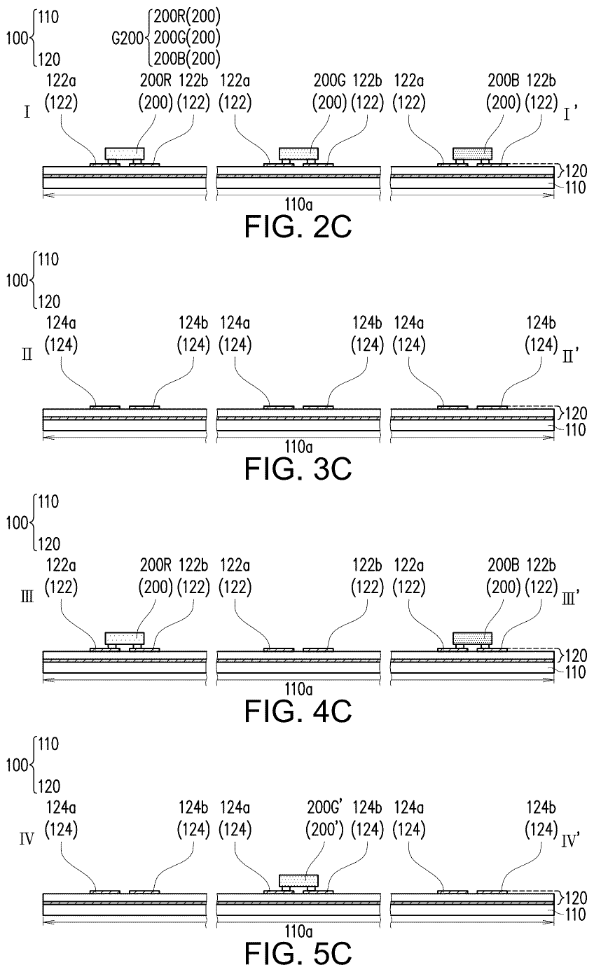

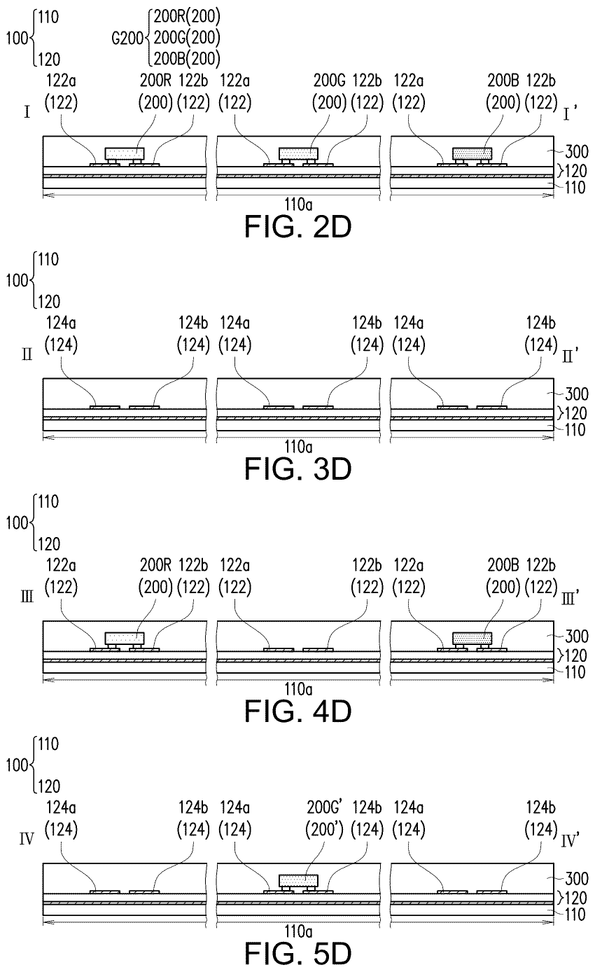

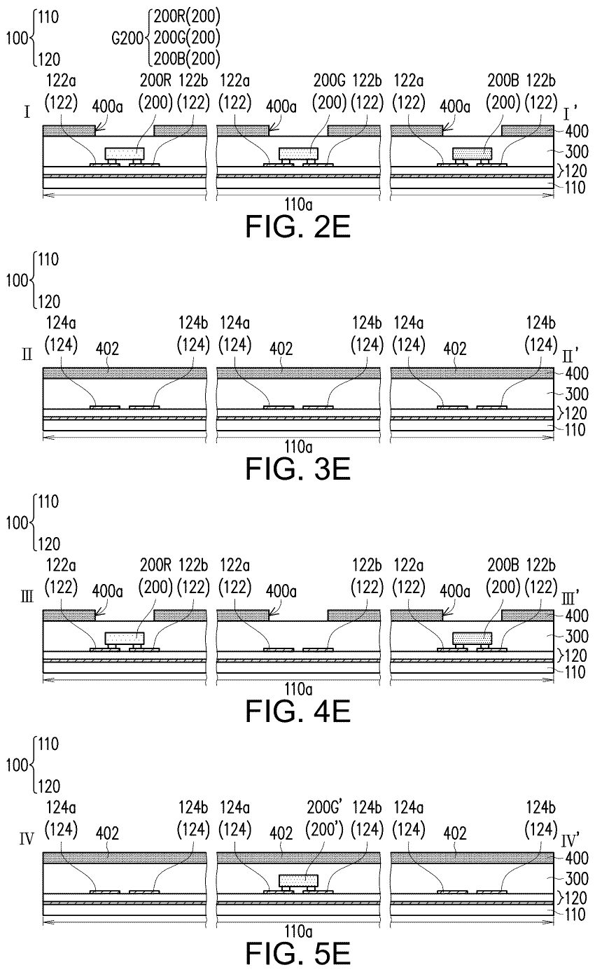

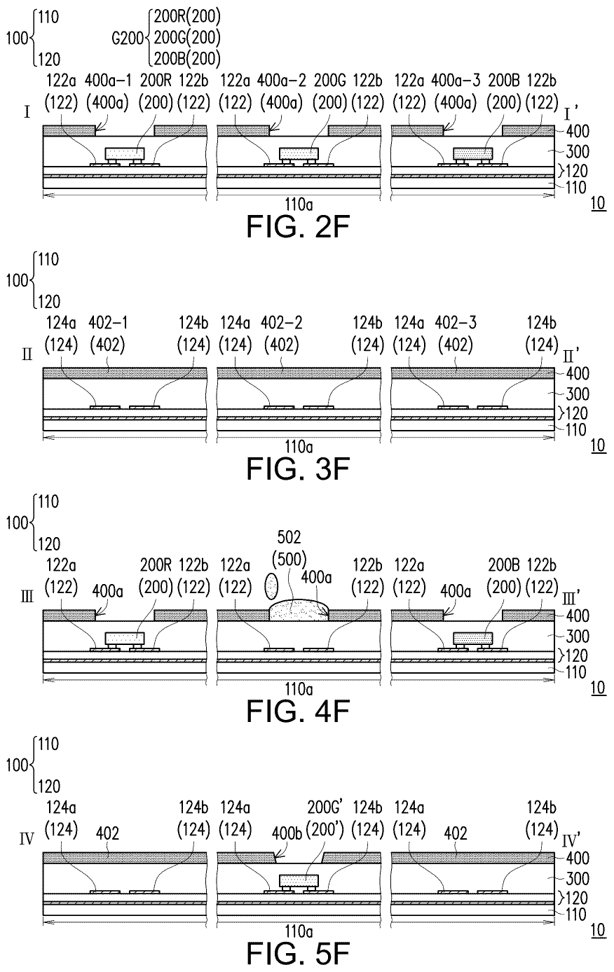

FIG. 1A to FIG. 1F are top schematic views of a manufacturing process of a display apparatus according to an embodiment of the disclosure. FIG. 2A to FIG. 2F are cross-sectional schematic views of a manufacturing process of a display apparatus according to an embodiment of the disclosure. FIG. 2A to FIG. 2F respectively correspond to a section line I-I′ of FIG. 1A to FIG. 1F. FIG. 3A to FIG. 3F are cross-sectional schematic views of a manufacturing process of a display apparatus according to an embodiment of the disclosure. FIG. 3A to FIG. 3F respectively correspond to a section line II-II′ of FIG. 1A to FIG. 1F. FIG. 4A to FIG. 4F are cross-sectional schematic views of a manufacturing process of a display apparatus according to an embodiment of the disclosure. FIG. 4A to FIG. 4F respectively correspond to a section line III-III′ of FIG. 1A to FIG. 1F. FIG. 5A to FIG. 5F are cross-sectional schematic views of a manufacturing process of a display apparatus according to an embodiment of the disclosure. FIG. 5A to FIG. 5F respectively correspond to a section line IV-IV′ of FIG. 1A to FIG. 1F.

Please refer to FIG. 1A, FIG. 2A, FIG. 3A, FIG. 4A, and FIG. 5A. First, a driving circuit substrate 100 is provided. The driving circuit substrate 100 includes a base 110 and a circuit structure 120 disposed on the base 110. In some embodiments, the base 110 may selectively have a first area 110a and a second area 110b, the circuit structure 120 is disposed in the first area 110a of the base 110, the driving circuit substrate 100 is substantially opaque in the first area 110a, the circuit structure 120 is not disposed in the second area 110b of the base 110, and the driving circuit substrate 100 is translucent in the second area 110b, but the disclosure is not limited thereto.

Please refer to FIG. 1A, FIG. 2A, FIG. 3A, FIG. 4A, and FIG. 5A. The circuit structure 120 of the driving circuit substrate 100 has multiple pixel driving structures PX. Each pixel driving structure PX includes multiple sub-pixel driving structures SPX. For example, in some embodiments, each pixel driving structure PX may selectively include three sub-pixel driving structures SPX1, SPX2, and SPX3, but the disclosure is not limited thereto.

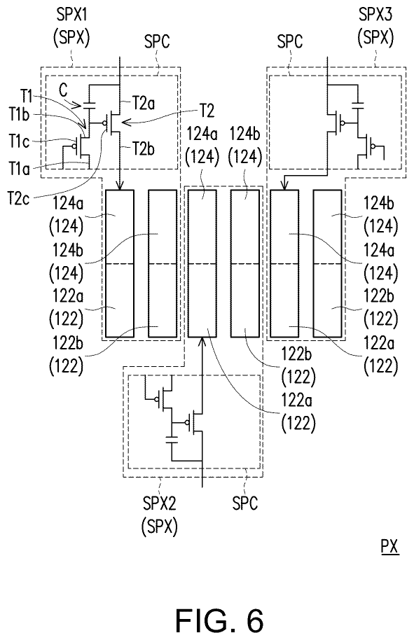

FIG. 6 is a schematic view of an equivalent circuit of a pixel driving structure of a display apparatus according to an embodiment of the disclosure. Please refer to FIG. 1A, FIG. 2A, FIG. 3A, FIG. 4A, FIG. 5A, and FIG. 6. Each pixel driving structure PX includes multiple sub-pixel driving structures SPX, each sub-pixel driving structure SPX includes a sub-pixel driving circuit SPC (shown in FIG. 6), at least one main pad 122, and at least one repair pad 124, wherein the at least one main pad 122 and the at least one repair pad 124 are electrically connected to the same sub-pixel driving circuit SPC.

For example, in some embodiments, at least one main pad 122 of each sub-pixel driving structure SPX may include multiple main pads 122a and 122b that are structurally separated from each other, and at least one repair pad 124 of each sub-pixel driving structure SPX may include multiple repair pads 124a and 124b that are structurally separated from each other, wherein the main pad 122a is electrically connected to the repair pad 124a, and the other main pad 122b is electrically connected to the other repair pad 124b.

Please refer to FIG. 1A and FIG. 6. In detail, in some embodiments, the circuit structure 120 further includes multiple data lines DL, multiple gate lines GL, multiple power lines PL, and multiple common lines (not shown), each sub-pixel driving circuit SPC may include a first transistor T1, a second transistor T2, and a capacitor C, a first terminal T1a of the first transistor T1 is electrically connected to the corresponding data line DL, a control terminal T1c of the first transistor T1 is electrically connected to the corresponding gate line GL, a second terminal Tib of the first transistor T1 is electrically connected to a control terminal T2c of the second transistor T2, a first terminal T2a of the second transistor T2 is electrically connected to the corresponding power line PL, the capacitor C is electrically connected to the second terminal Tib of the first transistor T1 and the first terminal T2a of the second transistor T2, a second terminal T2b of the second transistor T2 is electrically connected to the main pad 122a and the repair pad 124a, and the other main pad 122b and the other repair pad 124b are electrically connected to the corresponding common line, but the disclosure is not limited thereto. In some embodiments, the control terminals T1c of the first transistors T1 of the sub-pixel driving structures SPX of the same pixel driving structure PX may be selectively electrically connected to the same gate line GL, but the disclosure is not limited thereto.

Please refer to FIG. 1B, FIG. 2B, FIG. 3B, FIG. 4B, and FIG. 5B. Next, multiple light emitting elements 200 are bonded to the main pads 122 of the sub-pixel driving structures SPX of the pixel driving structures PX. The light emitting elements 200 may be divided into multiple light emitting element groups G200. The light emitting element groups G200 are respectively electrically connected to the pixel driving structures PX. In some embodiments, each light emitting element group G200 may include a light emitting element 200R, a light emitting element 200G, and a light emitting element 200B respectively electrically connected to the sub-pixel driving structures SPX of the same pixel driving structure PX. In some embodiments, the light emitting element 200R, the light emitting element 200G, and the light emitting element 200B may be respectively used to emit red light, green light, and blue light, but the disclosure is not limited thereto. In some embodiments, the light emitting element 200 is, for example, a micro light emitting diode (LED), but the disclosure is not limited thereto.

Please refer to FIG. 1B, FIG. 2B, FIG. 3B, FIG. 4B, and FIG. 5B. Next, a detection procedure is performed to detect whether the light emitting elements 200 may be driven by the driving circuit substrate 100 to emit light. In some embodiments, during the detection procedure, it is found that a light emitting element 200NG on the main pad 122 of the sub-pixel driving structure SPX of the pixel driving structure PX cannot emit light normally. Please refer to FIG. 1B, FIG. 1C, FIG. 2B, FIG. 2C, FIG. 3B, FIG. 3C, FIG. 4B, FIG. 4C, FIG. 5B, and FIG. 5C. Next, in some embodiments, the light emitting element 200NG that cannot emit light normally may be selectively removed, and a repair light emitting element 200′ may be bonded to the repair pad 124 of the same sub-pixel driving structure SPX.

Please refer to FIG. 1B, FIG. 1C, FIG. 2B, FIG. 2C, FIG. 3B, FIG. 3C, FIG. 4B, FIG. 4C, FIG. 5B, and FIG. 5C. For example, in some embodiments, the pixel driving structures PX may include a first pixel driving structure PX1 and a second pixel driving structure PX2. During the detection procedure, it is found that the light emitting elements 200 of the first pixel driving structure PX1 may all emit light normally, the first pixel driving structure PX1 may be referred to as a normal pixel driving structure, and the light emitting element group G200 composed of the light emitting elements 200 electrically connected to the first pixel driving structure PX1 may be referred to as a normal light emitting element group. During the detection procedure, it is found that the light emitting element 200NG of the sub-pixel driving structure SPX of the second pixel driving structure PX2 cannot emit light normally, the light emitting element 200NG that cannot emit light normally may be removed, and the repair light emitting element 200′ may be bonded to the repair pad 124 of the same sub-pixel driving structure SPX of the second pixel driving structure PX2. Please refer to FIG. 1C, FIG. 2C, FIG. 3C, FIG. 4C, and FIG. 5C. The second pixel driving structure PX2 may be referred to as a repaired pixel driving structure, and a light emitting element group G200′ composed of the light emitting elements 200 and 200′ electrically connected to the second pixel driving structure PX2 may be referred to as a repaired light emitting element group.

In some embodiments, the light emitting element 200NG that cannot emit light normally is, for example, the second light emitting element 200G for emitting green light, and the repair light emitting element 200′ for replacing the light emitting element 200NG that cannot emit light normally is another second light emitting element 200G′ for emitting green light, but the disclosure is not limited thereto.

Please refer to FIG. 1D, FIG. 2D, FIG. 3D, FIG. 4D, and FIG. 5D. Next, a planarization layer 300 is formed on the driving circuit substrate 100 to cover the light emitting elements 200 and 200′. The planarization layer 300 is disposed on the driving circuit substrate 100 and covers the light emitting element groups G200 and G200′. In some embodiments, the material of the planarization layer 300 may be an inorganic material (for example, silicon oxide, silicon nitride, silicon oxynitride, or a stacked layer of at least two of the above materials), an organic material, or a combination thereof.

Please refer to FIG. 1E, FIG. 2E, FIG. 3E, FIG. 4E, and FIG. 5E. Next, a first light shielding layer 400 is formed on the planarization layer 300. The first light shielding layer 400 is disposed on the planarization layer 300. The first light shielding layer 400 has multiple openings 400a. The openings 400a of the first light shielding layer 400 respectively overlap with the main pads 122 of the pixel driving structures PX. The openings 400a of the first light shielding layer 400 are located above the light emitting elements 200, and multiple solid portions 402 of the first light shielding layer 400 shield the repair pads 124 of the pixel driving structures PX. Please refer to FIG. 1E and FIG. 5E. In some embodiments, the second pixel driving structure PX2 is repaired, and the repair light emitting element 200′ is temporarily shielded by the solid portion 402 of the first light shielding layer 400.

In some embodiments, the display apparatus 10 (labelled in FIG. 1F, FIG. 2F, FIG. 3F, FIG. 4F, and FIG. 5F) may selectively be a transparent display apparatus, and the first light shielding layer 400 may selectively also have multiple openings 400c, wherein the area of each opening 400c is larger than the area of one opening 400a, the light emitting elements 200 of each pixel driving structure PX are surrounded by the corresponding openings 400c, and a user may view a scene behind the display apparatus 10 through the openings 400c.

Please refer to FIG. 1F and FIG. 5F. In some embodiments, next, a processing hole 400b is formed in the first light shielding layer 400, wherein the processing hole 400b overlaps with the repair light emitting element 200′. For example, in some embodiments, a laser etching procedure may be used to form the processing hole 400b in the first light shielding layer 400, but the disclosure is not limited thereto.

Please refer to FIG. 1F and FIG. 4F. In some embodiments, next, a second light shielding layer 500 is formed on the first light shielding layer 400 and the planarization layer 300. In some embodiments, inkjet printing may be selectively used to form the second light shielding layer 500, but the disclosure is not limited thereto. At this point, the display apparatus 10 is completed. The second light shielding layer 500 includes a light shielding pattern 502. The openings 400a of the first light shielding layer 400 includes the opening 400a located on the main pad 122 of the sub-pixel driving structure SPX2 of the second pixel driving structure PX2. The light shielding pattern 502 of the second light shielding layer 500 is filled in the opening 400a of the first light shielding layer 400 and shields the main pad 122 of the sub-pixel driving structure SPX2 of the second pixel driving structure PX2. Thus, the display apparatus 10 can not only shield the unused repair pad 124 using the first light shielding layer 400, but also shield the discarded main pad 122 through the second light shielding layer 500, so that the reflectivity can be greatly reduced.

Please refer to FIG. 1F, FIG. 2F, FIG. 3F, FIG. 4F, and FIG. 5F. The pixel driving structures PX of the display apparatus 10 include a normal pixel driving structure (that is, the first pixel driving structure PX1). The light emitting element groups G200 of the display apparatus 10 include a normal light emitting element group (that is, the light emitting element group G200 electrically connected to the first pixel driving structure PX1). The light emitting element 200R of the normal light emitting element group (that is, the light emitting element group G200 electrically connected to the first pixel driving structure PX1) is bonded to the main pad 122 of the sub-pixel driving structure SPX1 of the normal pixel driving structure (that is, the first pixel driving structure PX1). The light emitting element 200G of the normal light emitting element group (that is, the light emitting element group G200 electrically connected to the first pixel driving structure PX1) is bonded to the main pad 122 of the sub-pixel driving structure SPX2 of the normal pixel driving structure (that is, the first pixel driving structure PX1). The light emitting element 200G of the normal light emitting element group (that is, the light emitting element group G200 electrically connected to the first pixel driving structure PX1) is bonded to the main pad 122 of the sub-pixel driving structure SPX3 of the normal pixel driving structure (that is, the first pixel driving structure PX1).

Please refer to FIG. 1F and FIG. 3F. The solid portions 402 of the first light shielding layer 400 include a solid portion 402-1 for shielding the repair pad 124 of the sub-pixel driving structure SPX1 of the normal pixel driving structure (that is, the first pixel driving structure PX1), a solid portion 402-2 for shielding the repair pad 124 of the sub-pixel driving structure SPX2 of the normal pixel driving structure (that is, the first pixel driving structure PX1), and a solid portion 402-3 for shielding the repair pad 124 of the sub-pixel driving structure SPX3 of the normal pixel driving structure (that is, the first pixel driving structure PX1).

Please refer to FIG. 1F and FIG. 3F. The openings 400a of the first light shielding layer 400 include an opening 400a-1 located above the light emitting element 200R of the normal light emitting element group (that is, the light emitting element group G200 electrically connected to the first pixel driving structure PX1). The openings 400a of the first light shielding layer 400 include an opening 400a-2 located above the light emitting element 200G of the normal light emitting element group (that is, the light emitting element group G200 electrically connected to the first pixel driving structure PX1). The openings 400a of the first light shielding layer 400 include an opening 400a-3 located above the light emitting element 200B of the normal light emitting element group (that is, the light emitting element group G200 electrically connected to the first pixel driving structure PX1).

Please refer to FIG. 1F, FIG. 2F, FIG. 3F, FIG. 4F, and FIG. 5F. The pixel driving structures PX of the display apparatus 10 include a repaired pixel driving structure (that is, the second pixel driving structure PX2). The light emitting element groups G200 include a repaired light emitting element group (that is, the light emitting element group G200′ electrically connected to the second pixel driving structure PX2). Please refer to FIG. 1F and FIG. 5F. The light emitting element 200′ of the repaired light emitting element group (that is, the light emitting element group G200′ electrically connected to the second pixel driving structure PX2) is bonded to the repair pad 124 of the sub-pixel driving structure SPX2 of the repaired pixel driving structure (that is, the second pixel driving structure PX2). Please refer to FIG. 1F and FIG. 4F. In some embodiments, the light emitting element 200R of the repaired light emitting element group (that is, the light emitting element group G200′ electrically connected to the second pixel driving structure PX2) is bonded to the main pad 122 of the sub-pixel driving structure SPX1 of the repaired pixel driving structure (that is, the second pixel driving structure PX2), and the light emitting element 200B of the repaired light emitting element group (that is, the light emitting element group G200′ electrically connected to the second pixel driving structure PX2) is bonded to the main pad 122 of the sub-pixel driving structure SPX3 of the repaired pixel driving structure (that is, the second pixel driving structure PX2).

Please refer to FIG. 1F, FIG. 4F, and FIG. 5F. The first light shielding layer 400 further includes the opening 400a and the processing hole 400b. The opening 400a is located above the main pad 122 of the sub-pixel driving structure SPX2 of the repaired pixel driving structure (that is, the second pixel driving structure PX2). The processing hole 400b is located above the repair pad 124 of the sub-pixel driving structure SPX2 of the repaired pixel driving structure (that is, the second pixel driving structure PX2) and the light emitting element 200′ of the repaired light emitting element group (that is, the light emitting element group G200′ electrically connected to the second pixel driving structure PX2). Please refer to FIG. 1F and FIG. 5F. The display apparatus 10 further includes the second light shielding layer 500 disposed on the planarization layer 300 and the first light shielding layer 400. The second light shielding layer 500 includes the light shielding pattern 502 filled in the opening 400a of the first light shielding layer 400. The light shielding pattern 502 shields the main pad 122 of the sub-pixel driving structure SPX2 of the repaired pixel driving structure (that is, the second pixel driving structure PX2).

What is claimed is:

1. A display apparatus, comprising:
a driving circuit substrate, having a plurality of pixel driving structures, wherein each of the pixel driving structures comprises a plurality of sub-pixel driving structures, each of the sub-pixel driving structures comprises a sub-pixel driving circuit, at least one main pad, and at least one repair pad, and the at least one main pad and the at least one repair pad are electrically connected to the sub-pixel driving circuit;
a plurality of light emitting element groups, respectively electrically connected to the pixel driving structures, wherein each of the light emitting element groups comprises a first light emitting element;
a planarization layer, disposed on the driving circuit substrate and covering the light emitting element groups; and
a first light shielding layer, disposed on the planarization layer, wherein the pixel driving structures comprise a normal pixel driving structure, the light emitting element groups comprise a normal light emitting element group, the normal light emitting element group is electrically connected to the normal pixel driving structure, the first light emitting element of the normal light emitting element group is bonded to the at least one main pad of the normal pixel driving structure, and the first light shielding layer comprises:
a first solid portion, shielding the at least one repair pad of the normal pixel driving structure; and
a first opening, located above the first light emitting element of the normal light emitting element group.

2. The display apparatus according to claim 1, wherein the sub-pixel driving structures of each of the pixel driving structures comprise a first sub-pixel driving structure and a second sub-pixel driving structure, and each of the light emitting element groups further comprises a second light emitting element, the first light emitting element of the normal light emitting element group is bonded to the at least one main pad of the first sub-pixel driving structure of the normal pixel driving structure, the second light emitting element of the normal light emitting element group is bonded to the at least one main pad of the second sub-pixel driving structure of the normal pixel driving structure, the first light shielding layer further comprises a second solid portion and a second opening, the second solid portion shields the at least one repair pad of the second sub-pixel driving structure of the normal pixel driving structure, and the second opening is located above the second light emitting element of the normal light emitting element group.

3. The display apparatus according to claim 2, wherein the sub-pixel driving structures of each of the pixel driving structures further comprise a third sub-pixel driving structure, each of the light emitting element groups further comprises a third light emitting element, the third light emitting element of the normal light emitting element group is bonded to the at least one main pad of the third sub-pixel driving structure of the normal pixel driving structure, the first light shielding layer further comprises a third solid portion and a third opening, the third solid portion shields the at least one repair pad of the third sub-pixel driving structure of the normal pixel driving structure, and the third opening is located above the third light emitting element of the normal light emitting element group.

4. The display apparatus according to claim 1, wherein the sub-pixel driving structures of each of the pixel driving structures comprise a second sub-pixel driving structure, each of the light emitting element groups further comprises a second light emitting element, the pixel driving structures comprise a repaired pixel driving structure, the light emitting element groups comprise a repaired light emitting element group, the repaired light emitting element group is electrically connected to the repaired pixel driving structure, the second light emitting element of the repaired light emitting element group is bonded to the at least one repair pad of the second sub-pixel driving structure of the repaired pixel driving structure, the first light shielding layer further comprises a second opening and a processing hole, the second opening is located above the at least one main pad of the second sub-pixel driving structure of the repaired pixel driving structure, the processing hole is located above the at least one repair pad of the second sub-pixel driving structure of the repaired pixel driving structure and the second light emitting element of the repaired light emitting element group.

5. The display apparatus according to claim 4, further comprising:
a second light shielding layer, disposed on the planarization layer and the first light shielding layer, wherein the second light shielding layer comprises a light shielding pattern filled in the second opening of the first light shielding layer, and the light shielding pattern shields the at least one main pad of the second sub-pixel driving structure of the repaired pixel driving structure.

6. A manufacturing method of a display apparatus, comprising:
providing a driving circuit substrate having a plurality of pixel driving structures, wherein each of the pixel driving structures comprises a plurality of sub-pixel driving structures, each of the sub-pixel driving structures comprises a sub-pixel driving circuit, at least one main pad, and at least one repair pad, and the at least one main pad and the at least one repair pad are electrically connected to the sub-pixel driving circuit;
bonding a plurality of light emitting elements to a plurality of main pads of the sub-pixel driving structures of the pixel driving structures;
forming a planarization layer on the driving circuit substrate to cover the light emitting elements; and
forming a first light shielding layer on the planarization layer, wherein the first light shielding layer has a plurality of openings, the openings are located above at least part of the light emitting elements, and a plurality of solid portions of the first light shielding layer shield at least part of a plurality of repair pads of the pixel driving structures.

7. The manufacturing method of the display apparatus according to claim 6, further comprising:
after bonding the light emitting elements to the main pads, performing a detection procedure to detect whether the light emitting elements are driven by the driving circuit substrate to emit light, wherein during the detection procedure, one of the light emitting elements on the at least one main pad of one of the sub-pixel driving structures of one of the pixel driving structures is found to be unable to emit light;
after performing the detection procedure and before forming the planarization layer, bonding a repair light emitting element to the at least one repair pad of the sub-pixel driving structure; and
forming a processing hole in the first light shielding layer, wherein the processing hole overlaps with the repair light emitting element.

8. The manufacturing method of the display apparatus according to claim 7, further comprising:
forming a second light shielding layer on the first light shielding layer and the planarization layer, wherein the second light shielding layer comprises a light shielding pattern, the openings comprise an opening located on the at least one main pad of the sub-pixel driving structure of the pixel driving structure, and the light shielding pattern is filled in the opening of the first light shielding layer and shields the at least one main pad of the sub-pixel driving structure of the pixel driving structure.

9. A display apparatus, comprising:
a driving circuit substrate, having a plurality of pixel driving structures, wherein each of the pixel driving structures comprises a plurality of sub-pixel driving structures, each of the sub-pixel driving structures comprises a sub-pixel driving circuit, at least one main pad, and at least one repair pad, and the at least one main pad and the at least one repair pad are electrically connected to the sub-pixel driving circuit;
a plurality of light emitting element groups, respectively electrically connected to the pixel driving structures, wherein each of the light emitting element groups comprises a first light emitting element;
a planarization layer, disposed on the driving circuit substrate and covering the light emitting element groups; and
a first light shielding layer, disposed on the planarization layer, wherein the pixel driving structures comprise a normal pixel driving structure, the light emitting element groups comprise a normal light emitting element group, the normal light emitting element group is electrically connected to the normal pixel driving structure, the first light emitting element of the normal light emitting element group is bonded to the at least one main pad of the normal pixel driving structure, and the first light shielding layer comprises:
a first solid portion, shielding the at least one repair pad of the normal pixel driving structure; and
a first opening, located above the first light emitting element of the normal light emitting element group;
wherein the sub-pixel driving structures of each of the pixel driving structures comprise a first sub-pixel driving structure and a second sub-pixel driving structure, each of the light emitting element groups further comprises a second light emitting element, the first light emitting element of the normal light emitting element group is bonded to the at least one main pad of the first sub-pixel driving structure of the normal pixel driving structure, the second light emitting element of the normal light emitting element group is bonded to the at least one main pad of the second sub-pixel driving structure of the normal pixel driving structure, the first light shielding layer further comprises a second solid portion and a second opening, the second solid portion shields the at least one repair pad of the second sub-pixel driving structure of the normal pixel driving structure, and the second opening is located above the second light emitting element of the normal light emitting element group;
wherein the first light emitting element and the second light emitting element are respectively used to emit a red light and a green light.

10. The display apparatus according to claim 9, wherein the sub-pixel driving structures of each of the pixel driving structures further comprise a third sub-pixel driving structure, each of the light emitting element groups further comprises a third light emitting element, the third light emitting element of the normal light emitting element group is bonded to the at least one main pad of the third sub-pixel driving structure of the normal pixel driving structure, the first light shielding layer further comprises a third solid portion and a third opening, the third solid portion shields the at least one repair pad of the third sub-pixel driving structure of the normal pixel driving structure, and the third opening is located above the third light emitting element of the normal light emitting element group.

11. The display apparatus according to claim 10, wherein the third light emitting element is used to emit a blue light.

12. The display apparatus according to claim 9, wherein the sub-pixel driving structures of each of the pixel driving structures comprise a second sub-pixel driving structure, each of the light emitting element groups further comprises a second light emitting element, the pixel driving structures comprise a repaired pixel driving structure, the light emitting element groups comprise a repaired light emitting element group, the repaired light emitting element group is electrically connected to the repaired pixel driving structure, the second light emitting element of the repaired light emitting element group is bonded to the at least one repair pad of the second sub-pixel driving structure of the repaired pixel driving structure, the first light shielding layer further comprises a second opening and a processing hole, and the second opening is located above the at least one main pad of the second sub-pixel driving structure of the repaired pixel driving structure.

13. The display apparatus according to claim 12, wherein the processing hole is located above the at least one repair pad of the second sub-pixel driving structure of the repaired pixel driving structure and the second light emitting element of the repaired light emitting element group.

14. The display apparatus according to claim 11, further comprising:
a second light shielding layer, disposed on the planarization layer and the first light shielding layer, wherein the second light shielding layer comprises a light shielding pattern filled in the second opening of the first light shielding layer.

15. The display apparatus according to claim 14, wherein the light shielding pattern shields the at least one main pad of the second sub-pixel driving structure of the repaired pixel driving structure.
